(19) United States
(12) Patent Application Publication
(10) Pub. No.: US 2002/0155693 A1
(43) Pub. Date: Oct. 24, 2002

(54) Method to form self-aligned anti-via interconnects

(75) Inventors: Sangki Hong, Singapore (SG); Subhash Gupta, Singapore (SG); Kwok Keung Paul Ho, Singapore (SG)

Correspondence Address: GEORGE O. SAILE, 20 MCINTOSH DRIVE, POUGHKEEPSIE, NY, 12603, US

(73) Assignee: Chartered Semiconductor Manufacturing Ltd.

(21) Appl. No.: 09/839,963

(22) Filed: Apr. 23, 2001

(51) Int. Cl. H01L 21/4763

(52) U.S. Cl. 438/618; 438/638; 438/639

(57) ABSTRACT

A new method of fabricating self-aligned, anti-via interconnects has been achieved. A semiconductor substrate is provided. A metal layer is deposited overlying the semiconductor substrate. The metal layer may comprise a composite stack of two metal layers. The metal layers may additionally be separated by an etch stopping layer. An anti-reflective coating layer is deposited overlying the metal layer. The metal layer is etched through to form connective lines. The metal layer is then etched partially through to form vias. The partial etching through may be accomplished by timed etching or by use of the optional etching stop layer. A dielectric layer is deposited overlying the vias, the connective lines and the semiconductor substrate. The dielectric layer may comprise a low-k material. The dielectric layer is polished down to complete the self-aligned, anti-via interconnects in the manufacture of the integrated circuit device.

### BACKGROUND OF THE INVENTION

(1) Field of the Invention

The invention relates to a method of fabricating semiconductor devices, and more particularly, to the fabrication of interconnect structures with self-aligned, anti-vias in the manufacture of an integrated circuit device.

(2) Description of the Prior Art

The formation of high quality interconnects is a critical part of ultra large-scale integration (ULSI) integrated circuits. In recent years, damascene processes, whereby connective line and via openings are pre-formed in a dielectric layer prior to the deposition of metal, have been added to the traditional method of depositing and etching metal followed by dielectric formation. Each approach offers advantages and disadvantages for the process integration. Metal etching problems can be traded for dielectric etching problems, for example.

Referring now to FIG. 1, a cross-section of a prior art integrated circuit device is illustrated. In this device, a popular scheme for the integration of aluminum-based interconnects and low-k dielectrics is shown. An isolation layer 14 overlies the semiconductor substrate 10. A first metal layer 18, comprising aluminum, is deposited overlying the isolation layer 14. A capping layer 20 is formed overlying the first metal layer 18. After the capping layer 20 and first metal layer 18 are patterned to form connective lines, a low-k dielectric layer 22 is deposited. The low-k dielectric layer 22 comprises, for example, an organic material that is designed to have a low dielectric constant. A second dielectric layer 26, such as silicon dioxide, is then deposited overlying the low-k dielectric layer 22.

Referring now to FIG. 2, via openings 30 are etched through the second dielectric layer 26 and the low-k dielectric layer 22. The via openings 30 expose the top surface of the connective lines 18 and 20. The via openings 30 are etched using a dry plasma etching process. Note that the low-k dielectric layer 22 may experience via poisoning during the etch process. In addition, the combined poisoning that occurs during the etch, clean and resist strip processes results in significant bowing 34 and enlargement of the opening. The problems encountered in the etching, cleaning and stripping processes make it difficult to integrate low-k dielectric materials and aluminum interconnects.

Several prior art approaches disclose methods to form interconnects in the manufacture of an integrated circuit device. U.S. Pat. No. 5,512,514 to Lee teaches a method to form an integral via and contact interconnect. A metal layer or a multilevel metal layer is deposited. Vias are patterned into the metal layer by etching the metal layer partially down. The interconnect lines are then patterned by etching through the metal layer. This technique necessitates the deposition and patterning of the photoresist for the interconnect lines be performed on a non-planar metal surface. U.S. Pat. No. 5,693,568 to Liu et al discloses a method to form reverse damascene interconnects. The method does not provide a polishing stop for the polishing down of the intermetal dielectric layer and, therefore, metal damage could occur in this process. U.S. Pat. No. 4,917,759 to Fisher et al teaches a method to form self-aligned vias. A second conductive layer is patterned to form a hard mask overlying a first conductive layer. A third conductive layer is then deposited to thereby embed the second conductive hard mask. The third and first conductive layers are then sequentially etched. U.S. Pat. No. 5,861,673 to Yoo et al teaches a method to extend the surface area of a metal region wherein a via contact is planned. U.S. Pat. No. 5,846,876 to Bandyopadhyay et al discloses a method to form damascene interconnects with staggered levels. U.S. Pat. No. 5,691,238 to Avanzino et al teaches a reverse damascene method. Openings are etched in a dielectric layer. A metal layer is deposited and polished down to form connective lines. Vias are then etched into the connective lines. A dielectric layer is then deposited and polished down to complete the structures.

### SUMMARY OF THE INVENTION

A principal object of the present invention is to provide an effective and very manufacturable method of fabricating self-aligned, anti-via interconnects in the manufacture of integrated circuits.

A further object of the present invention is to provide a method to fabricate interconnects where vias are inherently self-aligned to underlying connective lines.

Another further object of the present invention is to eliminate poisoning or bowing of the low-k intermetal dielectric layer by depositing the dielectric layer after formation of the connective line and via stack.

Yet another further object of the present invention is to eliminate loss of via metal due to low-k dielectric layer polish down through the use of a top protective layer.

In accordance with the objects of this invention, a new method of fabricating self-aligned, anti-vias has been achieved. A semiconductor substrate is provided. A metal layer is deposited overlying the semiconductor substrate. The metal layer may comprise a composite stack of two metal layers. The metal layers may additionally be separated by an etch stopping layer. An anti-reflective coating layer is deposited overlying the metal layer. The metal layer is etched through to form connective lines. The metal layer is then etched partially through to form vias. The partial etching through may be accomplished by timed etching or by use of the optional etching stop layer. A dielectric layer is deposited overlying the vias, the connective lines and the semiconductor substrate. The dielectric layer may comprise a low-k material. The dielectric layer is polished down to complete the self-aligned, anti-via interconnects in the manufacture of the integrated circuit device.

### BRIEF DESCRIPTION OF THE DRAWINGS

In the accompanying drawings forming a material part of this description, there is shown:

FIGS. 1 and 2 schematically illustrate in cross-section partially completed prior art integrated circuit devices.

FIGS. 3 through 10 schematically illustrate in cross-sectional representation a preferred embodiment of the present invention.

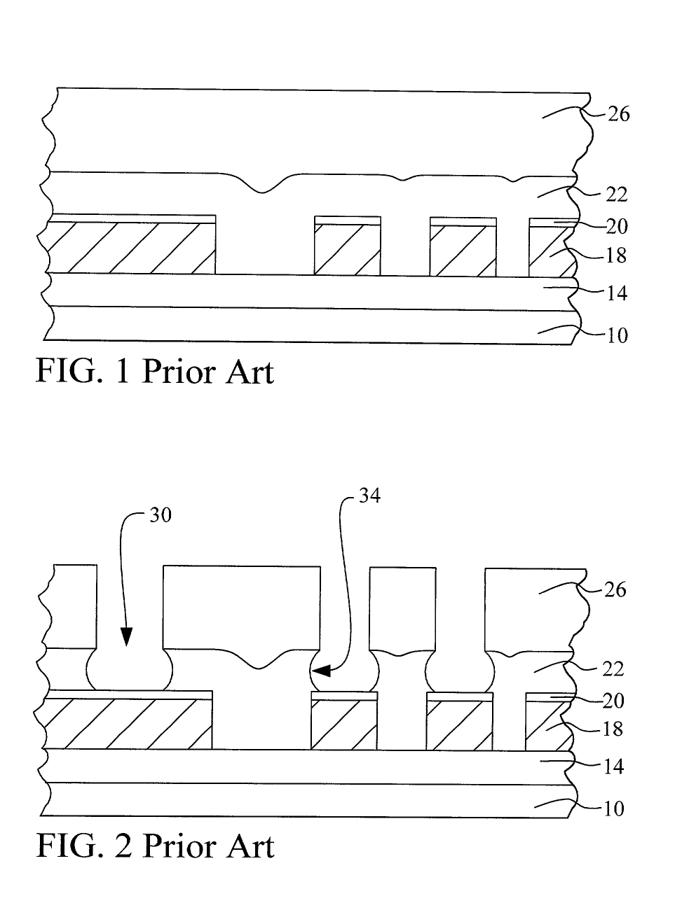

### DESCRIPTION OF THE PREFERRED EMBODIMENTS

The method of the present invention is applied to the formation of self-aligned, anti-via interconnects in a semiconductor substrate. In should be clear to those experienced in the art that the present invention can be applied and extended without deviating from the scope of the present invention.

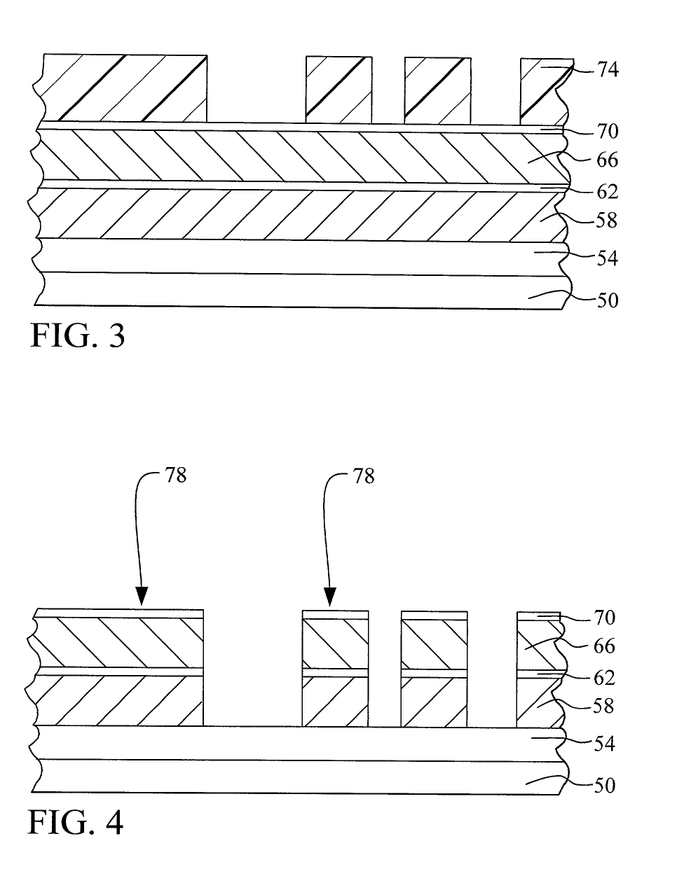

Referring now more particularly to FIG. 3, there is illustrated a cross-section of a partially completed integrated circuit device of the preferred embodiment. Several important features of the present invention are illustrated. A semiconductor substrate 50 is provided. Preferably, the semiconductor substrate 50 comprises monocrystalline silicon fabricated by methods well known in the art. The semiconductor substrate 50 may additionally comprises layers, junctions, and devices typical to the art. An insulating layer 54 is formed overlying the semiconductor substrate 50 and covers any previously formed devices, if used. The insulating layer 54 comprises any dielectric material that is sufficient to insulate the semiconductor substrate 50 from the overlying metal structures. For example, the insulating layer 54 may comprise silicon dioxide.

Of particular importance to the present invention, a first metal layer 58 is deposited overlying the insulating layer 54. The first metal layer 58 comprises one of the group of: aluminum, aluminum alloys, tungsten and copper. The first metal layer 58 is later be patterned to form connective lines. The first metal layer 58 is preferably deposited to a thickness of between about 1,000 Angstroms and 10,000 Angstroms.

An etch stop layer 62 is deposited overlying the first metal layer 58. The purpose of the etch stop layer 62 is to allow complete etching through of the second metal layer 66 without damaging the underlying first metal layer 58. The etch stop layer 62 preferably comprises one of the group of: titanium nitride (TiN), titanium (T), tungsten (W), tungsten nitride (WN), tantalum (Ta), and tantalum nitride (TaN). The etch stop layer 62 is optional to the present invention. In the case where the etch stop layer 62 is not used, a timed etch must be used to allow independent etching of the first and second metal layers.

A second metal layer 66, which serves as a via interconnecting the two metal layer, is deposited overlying the etch stop layer 62. The second metal layer 66 will be patterned to form vias. The second metal layer 66 preferably comprises one of the group of: aluminum, aluminum alloys, tungsten, and copper. The second metal layer 66 is preferably deposited to a thickness of between about 3,000 Angstroms and 10,000 Angstroms. Note that, if the etch stop layer 62 comprises titanium (Ti), then the etch stop layer 62 may be converted to TiAl₃ during the deposition of the second metal layer 66.

An anti-reflective coating (ARC) layer 70 is deposited overlying the second metal layer 66. The ARC layer 70 preferably comprises titanium nitride (TiN). The ARC layer 70 fulfills two purposes in the present invention. First, the ARC layer 70 serves as a traditional anti-reflective coating to thereby improve photolithographic resolution for the photoresist patterning process. Second, the ARC layer 70 serves as a polishing stop for the polish down of the intermetal dielectric material. The ARC layer 70 is preferably deposited to a thickness of between about 300 Angstroms and 1,500 Angstroms.

Note that the metal stack comprises the first metal layer 58, the etch stop layer 62, the second metal layer 66, and the ARC layer 70. As indicated above, the etch stop layer 62 is optional. Further, in the case where the etch stop layer 62 is not used, the first metal layer 58 and the second metal layer 66 can become a single metal layer. In this case, the etching process for etching the vias must be carefully timed to insure that the connective lines are not etched through.

A first photoresist layer 74 is preferably deposited overlying the ARC layer 70. The first photoresist layer 74 is patterned to form a mask for etching the connective lines. The first photoresist layer 74 may be patterned using a conventional photolithographic sequence of exposure to actinic light through a reticle followed by development. Note that the presence of the ARC layer 70 enhances the resolution of the photolithographic process.

Referring now to FIG. 4, the ARC layer 70, the second metal layer 66, the etch stop layer 62, and the first metal layer 58 are etched through to form connective lines 78 in the first metal layer 58. Preferably, a dry plasma etch with an anisotropic etching profile is used. The presence of the patterned first photoresist layer 74 prevents unwanted etching of the metal stack. Following the etch, the first photoresist layer 74 is removed by a stripping process. Note that the stripping process does not impact the intermetal dielectric layer, as in the prior art example, since the interconnect dielectric layer is not present at this step in the process.

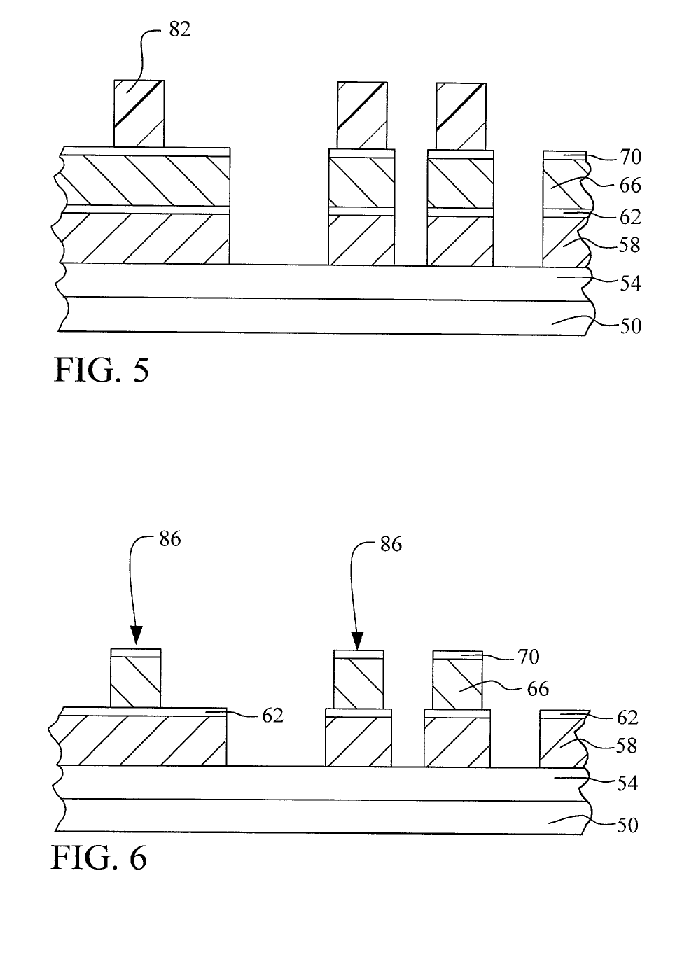

Referring now to FIG. 5, another important feature of the present invention is illustrated. A second photoresist layer 82 is deposited overlying the ARC layer 70. The second photoresist layer 82 is patterned to form a negative image of the planned vias. The second photoresist layer 82 may be patterned, for example, using a conventional photolithographic process wherein it is exposed to actinic light through a reticle and then developed to remove the unwanted resist. Note that the ARC layer 70 again improves the resolution of the photolithographic process. In addition, note that the critical patterning of the second photoresist layer 82 occurs over a planar portion of the metal stack. This advantage of the present invention is made possible for two reasons. First, the connective lines are etched before the vias. Second, the vias are smaller than, and contained within, the pattern for the connective traces. This is a significant advantage over prior art.

Referring now to FIG. 6, the ARC layer 70 and the second metal layer 66 are etched through to form vias 86. The patterned second photoresist layer 82 protects the vias 86 from etching. The etching step preferably comprises an anisotropic, dry plasma etch. Note that the etch stop layer 62 stops the etching process from attacking the underlying first metal layer 58. In this way, the second metal layer 66 is completely etched through without etching the first metal layer 58. In the case where an etch stop layer 62 is not used, this etching process must be a timed etch that is carefully controlled to insure that the via thickness and the connective line thickness are kept in specification.

The interconnect structure thus formed is a self-aligned, anti-via structure wherein the dual damascene structure is reversed. Following the second metal etch, the second photoresist layer 82 is stripped away. Once again, the intermetal dielectric does not experience the etching, cleaning, or photoresist stripping processes.

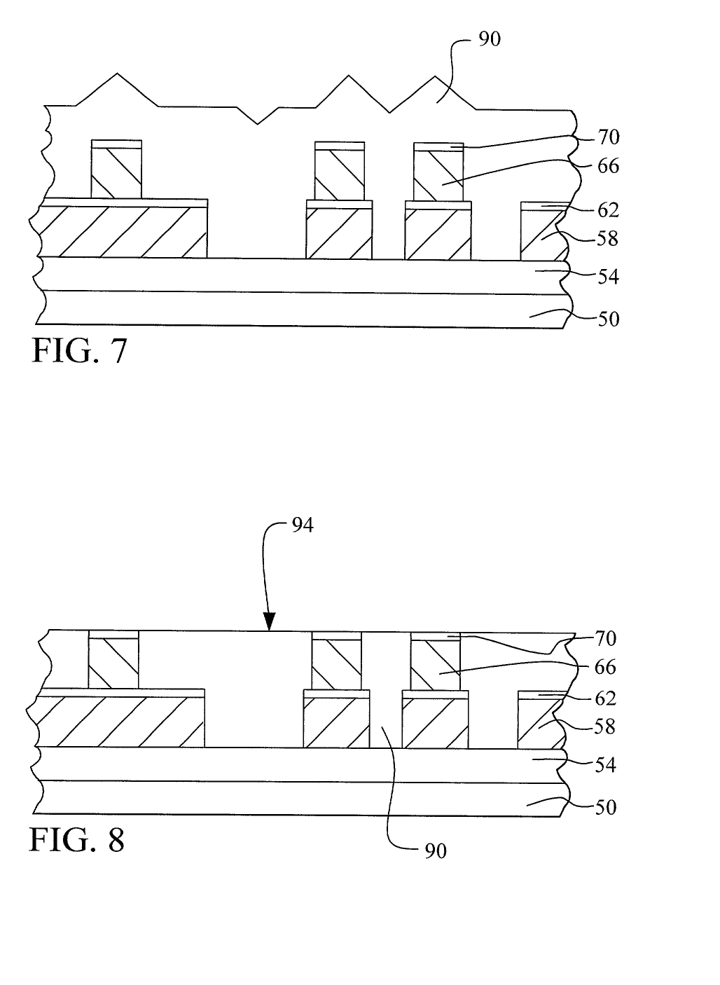

Referring now to FIG. 7, a dielectric layer 90 is deposited overlying the vias, the connective lines and the semiconductor substrate 50. The dielectric layer 90 forms the intermetal dielectric (IMD) for the interconnect structure. The dielectric layer 90 preferably comprises a low-k dielectric material. This dielectric layer 90 comprises, for example, any of the following: SiO₂; SiOF (fluorinated silica glass); SiOC (C-substituted siloxane); amorphous SiC:H; MSQ (methylsilsesquioxane); porous materials; polymers, such as PPXC (poly(chloro-p-xylylene)) and PPXN (poly-p-xylylene); and VT-4 (tetrafluoro-p-xylylene). The dielectric layer 90 may be deposited, for example, by spin-coating or by high density plasma CVD. The dielectric layer 90 is deposited to a thickness of between about 5,000 Angstroms and 20,000 Angstroms.

Referring now to FIG. 8, another important feature of the present invention is shown. The dielectric layer 90 is polished down to complete the self-aligned, anti-via interconnects in the manufacture of the integrated circuit device. The polishing down step is performed using a chemical mechanical polish (CMP). The titanium nitride, ARC layer 70 may serve as a polishing stop to protect the second metal layer 66 from the polishing process. A planar interconnect level 94 is thereby formed. Note that, since the dielectric layer 90 does not experience metal etching, cleaning, or photoresist stripping processes, no poisoning or bowing is seen.

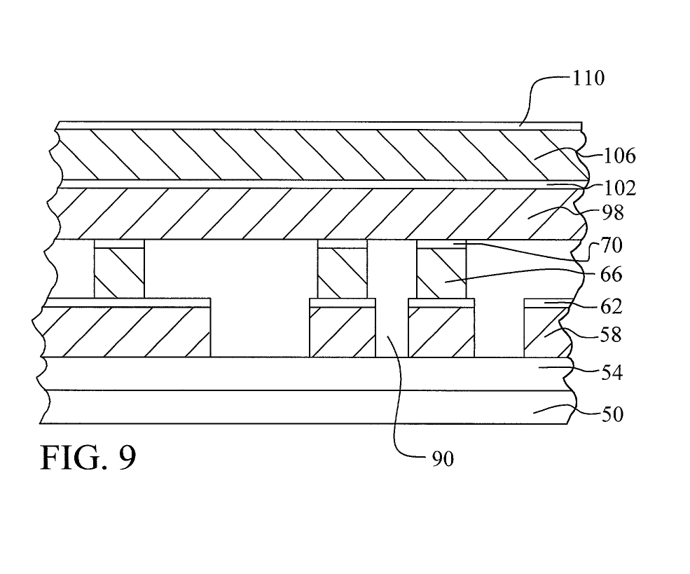

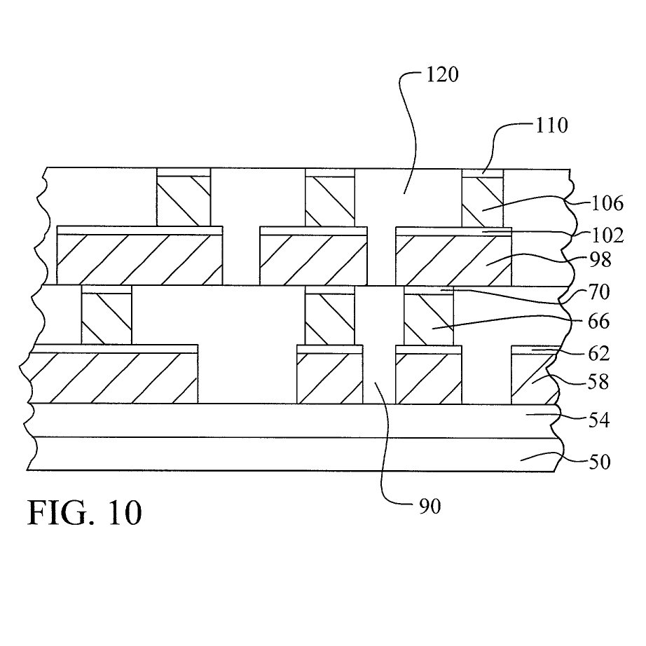

Referring now to FIG. 9, a second interconnect layer may be formed overlying the first layer. The second metal stack 98, 102, 106, and 110 is deposited overlying the first interconnect layer. Subsequent processing of the second metal stack is completed using the same process as that used for the first metal stack to create second-level connective lines 98 and 102 and to create second-level vias 106 and 110 as shown in FIG. 10. A second-level dielectric layer 120 is deposited and polished down to complete the second interconnect layer.

The advantages of the process of the present invention can now be enumerated. First, an effective process for forming interconnects in an integrated circuit device has been achieved. Second, the method allows the use of a low-k dielectric layer with an aluminum-based via and connective line configuration. Third, by first etching the connective line pattern and then the via pattern, a self-aligned, anti-via is formed. Fourth, the dielectric layer is not exposed to the metal etching, cleaning, or photoresist stripping processes. Fifth, the presence of the novel titanium nitride, ARC layer both improves the photolithography for the connective line and via definition and prevents polishing down damage.

As shown in the preferred embodiment, the present invention provides a very manufacturable process for fabricating self-aligned, anti-vias while in the manufacture of an integrated circuit device.

While the invention has been particularly shown and described with reference to the preferred embodiments thereof, it will be understood by those skilled in the art that various changes in form and details may be made without departing from the spirit and scope of the invention.

What is claimed is:

1. A method of forming self-aligned, anti-via interconnects in an integrated circuit device comprising:
providing a semiconductor substrate;
depositing a metal layer overlying said semiconductor substrate;
etching through said metal layer to form connective lines;
thereafter etching partially through said metal layer to form vias;
thereafter depositing a dielectric layer overlying said vias, said connective lines and said semiconductor substrate; and
polishing down said dielectric layer to complete said self-aligned, anti-via interconnects in the manufacture of the integrated circuit device.

2. The method according to claim 1 wherein said metal layer comprises one of the group of: aluminum, aluminum alloys, tungsten and copper.

3. The method according to claim 1 wherein said semiconductor substrate comprises semiconductor devices in and on a silicon substrate covered by an insulating layer.

4. The method according to claim 1 wherein said step of etching partially through said metal layer to form vias comprises a timed etch.

5. The method according to claim 1 wherein said dielectric layer comprises one of the group of: SiO₂, SiOF (fluorinated silica glass), SiOC (C-substituted siloxane), amorphous SiC:H, MSQ (methylsilsesquioxane), porous materials, PPXC polymer (poly(chloro-p-xylylene), PPXN polymer (poly-p-xylylene), and VT-4 (tetrafluoro-p-xylylene).

6. The method according to claim 1 wherein said dielectric layer is deposited to a thickness of between about 5,000 Angstroms and 20,000 Angstroms.

7. The method according to claim 1 further comprising depositing an anti-reflective coating layer overlying said metal layer prior to said step of etching through said metal layer to form connective lines.

8. The method according to claim 7 wherein said anti-reflective coating layer comprises titanium nitride (TiN) and wherein said anti-reflective coating layer is a polishing stop for said step of polishing down said dielectric layer.

9. A method of forming self-aligned, anti-via interconnects in an integrated circuit device comprising:
providing a semiconductor substrate;
depositing a first metal layer overlying said semiconductor substrate;
depositing a second metal layer overlying said first metal layer;
depositing an anti-reflective coating layer comprising titanium nitride (TiN) overlying said second metal layer;
etching through said anti-reflective coating layer, said second metal layer, and said first metal layer to form connective lines;
thereafter etching through said anti-reflective coating layer and said second metal layer to form vias;
thereafter depositing a dielectric layer overlying said vias, said connective lines and said semiconductor substrate; and
polishing down said dielectric layer to complete said self-aligned, anti-via interconnects in the manufacture of the integrated circuit device wherein said anti-reflective coating layer is a polishing stop.

10. The method according to claim 9 wherein said first metal layer and said second metal layer comprise one of the group of: aluminum, aluminum alloys, tungsten and copper.

11. The method according to claim 9 wherein said first metal layer is deposited to a thickness of between about 1,000 Angstroms and 10,000 Angstroms.

12. The method according to claim 9 wherein said second metal layer is deposited to a thickness of between about 3,000 Angstroms and 10,000 Angstroms.

13. The method according to claim 9 wherein said step of etching through said ARC layer and said second metal layer to form vias comprises a timed etch.

14. The method according to claim 9 further comprising depositing an etch stop layer after said step of depositing a first metal layer and before said step of depositing a second metal layer.

15. The method according to claim 14 wherein said step of etching through said ARC layer and said second metal layer to form vias has an endpoint at said etch stop layer.

16. The method according to claim 14 wherein said etch stop layer comprises one of the group of: titanium nitride (TiN), titanium (T), tungsten (W), tungsten nitride (WN), tantalum (Ta), and tantalum nitride (TaN).

17. The method according to claim 9 wherein said dielectric layer comprises one of the group of: SiO₂, SiOF (fluorinated silica glass), SiOC (C-substituted siloxane), amorphous SiC:H, MSQ (methylsilsesquioxane), porous materials, PPXC polymer (poly(chloro-p-xylylene), PPXN polymer (poly-p-xylylene), and VT-4 (tetrafluoro-p-xylylene).

18. A method of forming self-aligned, anti-via interconnects in an integrated circuit device comprising:
providing a semiconductor substrate;
depositing a first metal layer overlying said semiconductor substrate;
depositing an etch stop layer overlying said first metal layer;
depositing a second metal layer overlying said first metal layer;
depositing an anti-reflective coating layer comprising titanium nitride (TiN) overlying said second metal layer;
etching through said anti-reflective coating layer, said second metal layer, said etch stop layer, and said second metal layer to form connective lines;
thereafter etching through said anti-reflective coating layer and said second metal layer to form vias wherein said etch stop layer acts as an etch stop;
thereafter depositing a dielectric layer overlying said vias, said connective lines and said semiconductor substrate; and
polishing down said dielectric layer to complete said self-aligned, anti-via interconnects in the manufacture of the integrated circuit device wherein said anti-reflective coating layer is a polishing stop.

19. The method according to claim 18 wherein said first metal layer and said second metal layer comprise one of the group of: aluminum, aluminum alloys, tungsten, and copper.

20. The method according to claim 18 wherein said first metal layer is deposited to a thickness of between about 1,000 Angstroms and 10,000 Angstroms.

21. The method according to claim 18 wherein said second metal layer is deposited to a thickness of between about 3,000 Angstroms and 10,000 Angstroms.

22. The method according to claim 18 wherein said etch stop layer comprises one of the group of: titanium nitride (TiN), titanium (T), tungsten (W), tungsten nitride (WN), tantalum (Ta), and tantalum nitride (TaN).

23. The method according to claim 18 wherein said dielectric layer comprises one of the group of: SiO₂, SiOF (fluorinated silica glass), SiOC (C-substituted siloxane), amorphous SiC:H, MSQ (methylsilsesquioxane), porous materials, PPXC polymer (poly(chloro-p-xylylene), PPXN polymer (poly-p-xylylene), and VT-4 (tetrafluoro-p-xylylene).
